(19) United States
(12) Patent Application Publication
(10) Pub. No.: US 2026/0107400 A1
(43) Pub. Date: Apr. 16, 2026

(54) FLUID CONTROL APPARATUS

(71) Applicant: HORIBA STEC, Co., Ltd., Kyoto-shi (JP)

(72) Inventors: Masahiro NAKANE, Kyoto-shi (JP); Kohei HONDA, Kyoto-shi (JP)

(21) Appl. No.: 19/354,112

(22) Filed: Oct. 9, 2025

(30) Foreign Application Priority Data
Oct. 15, 2024 (JP) 2024-179777

(51) Int. Cl. H05K 5/06; F16K 27/12

(52) U.S. Cl. CPC H05K 5/069; F16K 27/12

(57) ABSTRACT

A fluid control valve 4 is provided outside a housing 6, and a through portion 61 through which passes a cable C that connects a connector 51 provided on a control board 5 to the fluid control valve 4 is formed in the housing 6, and there is provided a packing 7 that plugs a gap between a surface 61x of the housing 6 in which the through hole 61 is formed and the cable C.

### CROSS-REFERENCE TO RELATED APPLICATIONS

The present application claims priority to Japanese Patent Application No. JP2024-179777 filed October 15, 2024, which is incorporated herein by reference in its entirety.

### TECHNICAL FIELD

The present invention relates to a fluid control apparatus that controls a fluid flowing through a flow path.

### BACKGROUND ART

Conventionally, as is shown, for example, in Patent Document 1, a fluid control apparatus is provided with a body in an inside of which is formed a flow path, a fluid control valve that is attached to the body and controls a fluid flowing through the flow path, an electrical printed circuit board that controls the fluid control valve, and a casing that is mounted on the body. In this fluid control apparatus, the casing houses the fluid control valve and the printed circuit board, and the fluid control valve and the printed circuit board are electrically connected together by a cable.

### Prior Art Document

### Patent Document

Patent Document 1: Japanese Unexamined Patent Application (Laid-Open) No. 2023-66604

Here, in a case in which flow rate control is performed using the above-described fluid control apparatus, depending on the flow rate, there is a possibility that heat discharged from the fluid control valve will affect the printed circuit board. For this reason, it is necessary that the fluid control valve be located outside the casing in which the printed circuit board is housed.

In this case, because the cable that is used to connect the fluid control valve to the printed circuit board penetrates through the casing, there is a possibility that dust and moisture and the like will also enter the casing via this through portion in the casing. In particular, in a case in which the fluid control apparatus is located outdoors, there is an increased possibility that dust and moisture and the like will enter the inside of the casing.

### SUMMARY

The present invention was, therefore, conceived in view of the above-described problem and, in a structure in which a fluid control valve is disposed outside a housing, it is a principal object thereof to prevent dust and/or moisture from entering the inside of that housing.

In other words, a fluid control apparatus according to the present invention is a fluid control apparatus that controls a fluid flowing through a flow path, and is characterized in being provided with a fluid control valve that controls the fluid, a control board that controls the fluid control valve, and a housing that houses the control board, wherein the fluid control valve is disposed outside the housing, a through portion through which passes a cable that connects a connector provided on the control board to the fluid control valve is formed in the housing, and there is provided a packing that plugs a gap between a surface of the housing in which the through portion is formed and the cable.

If this type of structure is adopted, then because the packing is provided between the surface of the housing in which the through portion is formed and the cable so as to plug the gap between these, even if the fluid control valve is located outside the housing, it is still possible to prevent dust and moisture from entering the inside of the housing through the gap between the surface of the housing in which the through portion is formed and the cable. As a result, it is possible to prevent the control board and the like from malfunctioning because of dust and/or moisture.

Note that because the fluid control valve is located outside the housing, it is possible to prevent the control board and the like from malfunctioning because of heat discharged from the fluid control valve.

It is preferable that the housing include a housing main body that is formed in a cylindrical shape having at least an upper portion aperture formed therein, a lid body that covers the upper portion aperture in the housing main body, and a sealing component that is interposed between the housing main body and the lid body.

If this type of structure is adopted, then it is possible to form an airtight seal between the lid body and the housing main body by means of the sealing component.

It is also preferable that the through potion be formed by cutting a notch extending downwards from an upper end portion of the housing main body and/or extending upwards from a lower end portion of the housing main body, and that the packing have a sealing component abutting portion that, in a state in which the lid body is covering the upper portion aperture of the housing main body, abuts against the sealing component.

If this type of structure is adopted, then because the through portion is formed by cutting a notch extending downwards from an upper end portion of the housing main body, the cable can be passed directly through the through portion from the upper end portion of the housing main body, so that the ease of assembling the fluid control apparatus can be improved.

In addition, because the through portion is formed in the upper end portion of the housing main body so that, when the lid body is covering the upper portion aperture of the housing main body, the sealing component abutting portion of the packing abuts against the sealing component, the packing can be fixed to the housing main body by means of the sealing component.

It is also preferable that the housing include side wall portions that surround side portions of the control board, and that the through portion be formed in a side of the side wall portions that faces the fluid control valve.

If this type of structure is adopted, then because the through portion is formed in a side of the side wall portions that faces towards the fluid control valve, the cable is inserted through the space between the fluid control valve and the housing, and is connected to the connector via the through portion. Accordingly, because it is not necessary that the cable be wound around the outside of the housing, it is possible to reduce any likelihood of the cable being damaged such as, for example, if the cable were to become caught on a peripheral object or the like.

It is also preferable that an outside extension portion, which is a portion of the fluid control valve where the cable extends from the fluid control valve to the outside, be provided in a side of the fluid control valve that faces the through portion.

If this type of structure is adopted, then because the outside extension portion is provided in a side of the fluid control valve that faces the through portion, it is possible to shorten the length of the cable. As a result, it is possible to reduce even further any likelihood of the cable being damaged, and to also reduce the cost of providing the cable.

Moreover, because the outside extension portion is provided in the side of the fluid control valve that faces the through portion, it is possible to shorten the section of the cable that is exposed to the outside, so that it is possible to prevent the cable from being affected by external electrical noise.

It is also preferable that the packing include an outer side sealing portion that seals an outer surface of the housing in which the through portion is formed, and an inner side sealing portion that seals an inner surface of the housing in which the through portion is formed.

If this type of structure is adopted, because the outer side sealing portion and the inner side sealing portion seal the outer surface and the inner surface respectively of the housing, it is possible to further improve the sealability of the inside of the housing.

It is also preferable that the outer side sealing portion and the inner side sealing portion be mutually connected together, and that they sandwich both surfaces of the housing in which the through portion is formed.

If this type of structure is adopted, then because the outer side sealing portion and the inner side sealing portion are mutually connected, and sandwich the outer surface and the inner surface of the housing in which the through portion is formed, it is possible to prevent the packing from coming loose and falling from the inner side of the housing and the outer side of the housing.

It is also preferable that the packing include an annular portion that is formed having an annular shape and in which a holding aperture that holds the cable is formed so as to penetrate the packing in the thickness direction thereof, and a slit that is formed extending from an outer side circumferential surface of the annular portion towards the holding aperture, and that enables the cable to be fitted into the holding aperture.

If this type of structure is adopted, then in a state in which the connector and the fluid control valve are connected together by the cable, it is possible to insert the cable through the holding aperture in the packing via the slit, and when the packing is fitted inside the housing, because force is exerted from the outer side circumferential surface of the annular portion towards the holding aperture, the holding aperture is able to hold the cable in an airtight seal.

It is also preferable that the sealing component be formed having a frame shape that follows an aperture rim of the upper portion aperture formed in the housing main body, and that a positioning portion that positions the sealing component be formed in the aperture rim of the upper portion aperture of the housing main body and/or in the lid.

If this type of structure is adopted, then because the sealing component is positioned by the positioning portion, it is possible to further improve the sealing performance of the sealing component.

It is also preferable that a through hole be formed in the lid body so as to penetrate from an upper surface to a lower surface thereof, and that the housing further include a surface sealing material that covers the through hole.

If this type of structure is adopted, then in a case in which a through hole such as, for example, a communication port or a maintenance hole or the like is formed in the lid body, it is possible to cover this through hole using the surface sealing material.

An example of a specific aspect of the above-described fluid control apparatus is an aspect in which there is further provided a flow path block inside which is formed the flow path, and in which the fluid control valve, the control board, and the housing are provided on one surface of the flow path block.

According to the present invention, in a structure in which the fluid control valve is provided outside the housing, it is possible to prevent dust and/or moisture from penetrating into the inside of the housing.

### BRIEF DESCRIPTION OF THE DRAWINGS

FIG. 1 is a cross-sectional view schematically showing a structure of a fluid control apparatus of a first embodiment of the present invention;

FIG. 2 is a plan view of the fluid control apparatus of the same embodiment;

FIG. 3 is an exploded perspective view of a housing of the same embodiment;

FIG. 4 is a cross-sectional view taken along a line A-A of the fluid control apparatus of the same embodiment;

FIG. 5 is a perspective view of a packing of the same embodiment;

FIG. 6 is a partially enlarged cross-sectional view of a portion indicated by a broken line in FIG. 1 of the same embodiment;

FIG. 7 is a perspective view of a fluid control apparatus of a second embodiment of the present invention;

FIG. 8 is an exploded perspective view of a housing of the second embodiment;

FIG. 9 is a perspective view of a lid body of the second embodiment; and

FIG. 10 is an enlarged perspective view of a portion indicated by a broken line in FIG. 7 of the second embodiment.

### DETAILED DESCRIPTION

### First Embodiment of the Present Invention

Hereinafter, a fluid control apparatus according to a first embodiment of the present invention will be described with reference to the drawings. Note that, in order to simplify an understanding thereof, each of the drawings depicted below is shown schematically with omissions or enhancements made where these have been deemed appropriate. In addition, component elements that are the same in the respective drawings are indicated by the same descriptive symbols and any duplicated description thereof is omitted.

### Apparatus Structure

A fluid control apparatus 100 of the present embodiment is provided on a gas flow path through which a gas flows, and controls a flow rate of the gas flowing through that gas flow path.

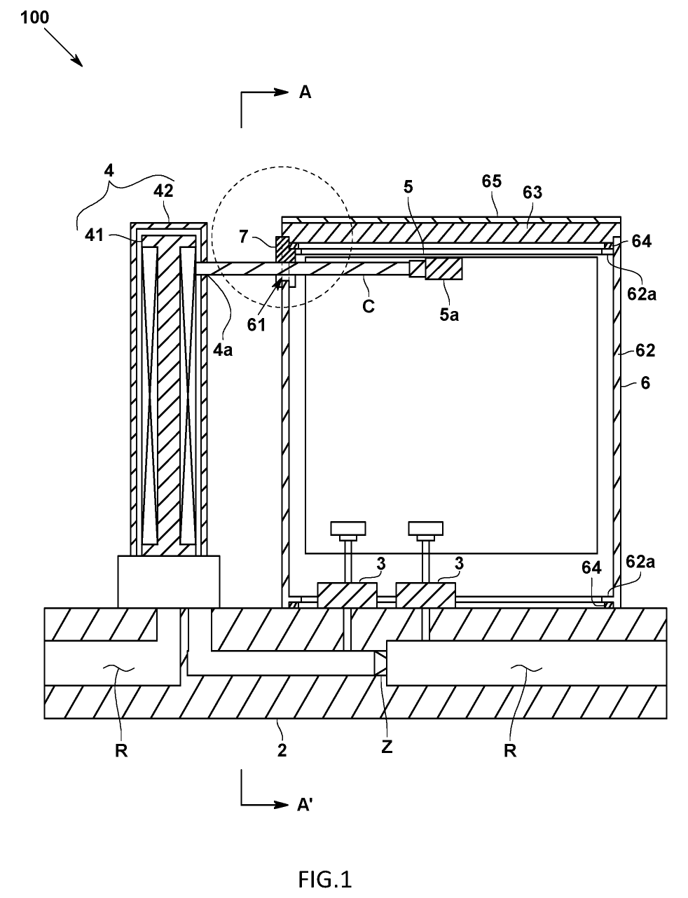

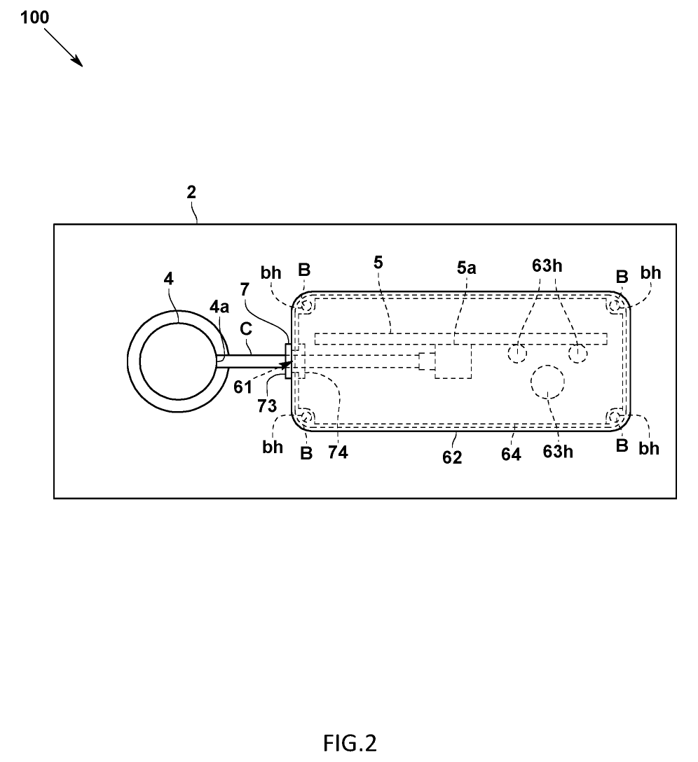

More specifically, as is shown in FIG. 1 and FIG. 2, the fluid control apparatus 100 is provided with a flow path block 2 inside which is formed a flow path R through which flows a fluid such as a gas or the like, a fluid sensor 3 that measures a flow rate of the fluid flowing through the flow path R, a fluid control valve 4 that controls the fluid, a control board 5 that controls the fluid control valve 4, and a housing 6 inside which is housed a least the control board 5. Hereinafter, the structure of each of these portions will be described.

The flow path block 2 may be formed, for example, in a rectangular shape with the fluid sensor 3, fluid control valve 4, control board 5, and housing 6 mounted on one predetermined surface thereof. An entry port (not shown in the drawings) through which a fluid is introduced into the flow path R, and an exit port (not shown in the drawings) through which a fluid is discharged from the flow path R are provided in the flow path block 2.

Here, the fluid sensor 3 is formed by a differential fluid pressure sensor. More specifically, the fluid sensor 3 is provided with an upstream-side pressure sensor 3a that is disposed on an upstream side of a resistive element Z such as a restrictor or an orifice that is provided in the flow path R, and a downstream-side pressure sensor 3b that is disposed on a downstream side of the resistive element Z. Note that a flow rate is calculated by a flow rate calculation unit (not shown in the drawings) of the control board 5 (described below) from a differential pressure between the two pressure sensors 3a and 3b.

Here, the fluid control valve 4 is formed by an electromagnetic valve that utilizes a solenoid as the actuator. This fluid control valve 4 controls the flow rate as a result of a valve body being made to advance or retract relative to a valve seat by this solenoid. More specifically, the fluid control valve 4 is provided with a solenoid 41 which serves as the actuator, and a casing 42 that contains the solenoid 41. Here, a cable C that electrically connects the fluid control valve 4 to the control board 5 extends from the casing 42 to the control board 5. Note that the fluid control valve 4 is controlled by a valve control unit (not shown in the drawings) of the control board 5 (described below).

The control board 5 is fixed to the housing 6 in a state of standing upright on one surface of the flow path block 2. More specifically, the control board 5 is formed by providing a CPU, memory, digital circuits such as communication circuits and the like, and analog circuits such as amplifiers and buffers and the like on a wiring substrate. As a result of the CPU and peripheral devices thereof operating in mutual collaboration in accordance with a program stored in the memory, the control board 5 is made to function as a flow rate calculation unit that calculates a flow rate of a fluid flowing through the flow path R based on pressures measured by the fluid sensor 3, and as a valve control unit that controls the fluid control valve 4 in such a way that the calculated flow rate matches a predetermined target flow rate.

Note that the control board 51 may also be separated into a substrate that functions as a flow rate calculation unit, and a substrate that functions as a valve control unit. In this case, the fluid sensor 3 is connected to the substrate that functions as a flow rate calculation unit, and the fluid control valve 4 is connected to the substrate that functions as a valve control unit.

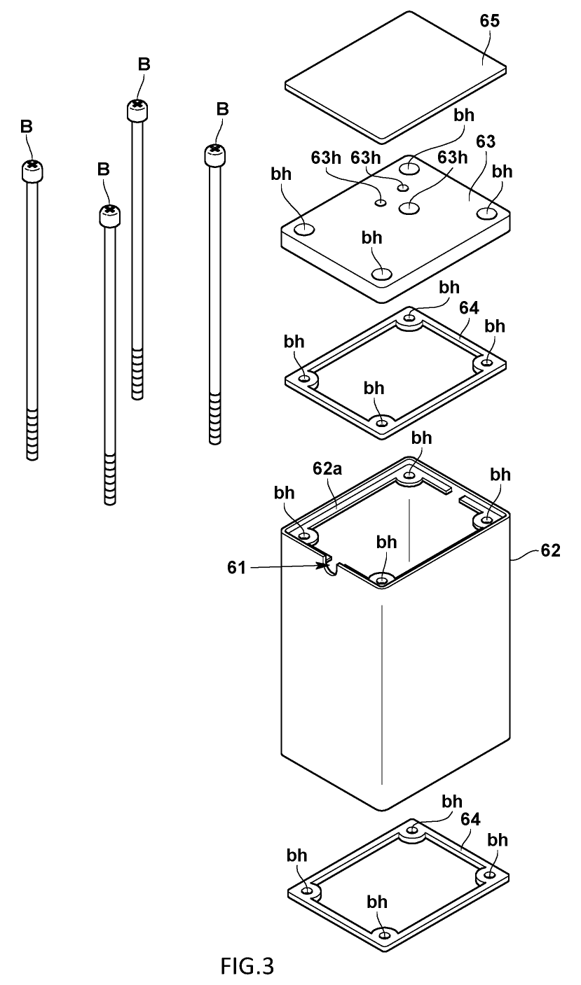

As is shown in FIG. 1 through FIG. 3, the housing 6 may be formed, for example, in a rectangular parallelepiped shape having an internal space inside which are housed the flow rate sensor 3 and the control board 5. The fluid control valve 4 is disposed outside the housing 6 and, as is shown in FIG. 3, a through portion 61, which is a space through which the cable C that connects the fluid control valve 4 to a connector 5a provided on the control board 5 is inserted, is formed in the housing 6. More specifically, as is shown in FIG. 3 in particular, the housing 6 includes a housing main body 62 that is formed in a cylindrical shape having at least an upper portion aperture, a lid body 63 that covers the upper portion aperture of the housing main body 62, and a sealing component 64 that is interposed between the housing main body 62 and the lid body 63. Hereinafter, a direction from the housing main body 62 towards the lid body 63 is described as upward, and a direction from the housing main body 62 towards the flow path block 2 is described as downward.

The housing main body 62 is formed by side wall portions that surround the sides of the control board 5, and in the present embodiment, is formed having a rectangular-cylinder shaped configuration whose upper end portion and lower end portion are open. As is shown in FIG. 1 and FIG. 2, one surface of the housing main body 62 faces the fluid control valve 4, and the through portion 61 is formed in this surface on the side of the housing main body 62 that faces the fluid control valve 4. More specifically, an outside extension portion 4a, which is a portion of the fluid control valve 4 where the cable C extends from the fluid control valve 4 to the outside, is formed in the fluid control valve 4, and this outside extension portion 4a is provided in the side thereof that faces the through portion 61. Note that it is also possible for the outside extension portion 4a to be provided on the opposite side from the through portion 61. Moreover, here, the outside extension portion 4a is an aperture portion that is formed in the casing 42 of the fluid control valve 4, however, the outside extension portion 4a may also be formed as a connector that is provided in the fluid control valve 4.

Here, as is shown in FIG. 1 and FIG. 2, the outside extension portion 4a, the through portion 61, and the connector 5a are all disposed on the same straight line. More specifically, as is shown in FIG. 1, the outside extension portion 4a, the through portion 61, and the connector 5a are all located at the same height when looked at in a cross-sectional view through the through portion 61 in a longitudinal direction in which the housing main body 62 extends. Note that it is also possible for the outside extension portion 4a, the through portion 61, and the connector 5a to be located at mutually different heights when looked at in a cross-sectional view through the through portion 61 in a longitudinal direction in which the housing main body 62 extends.

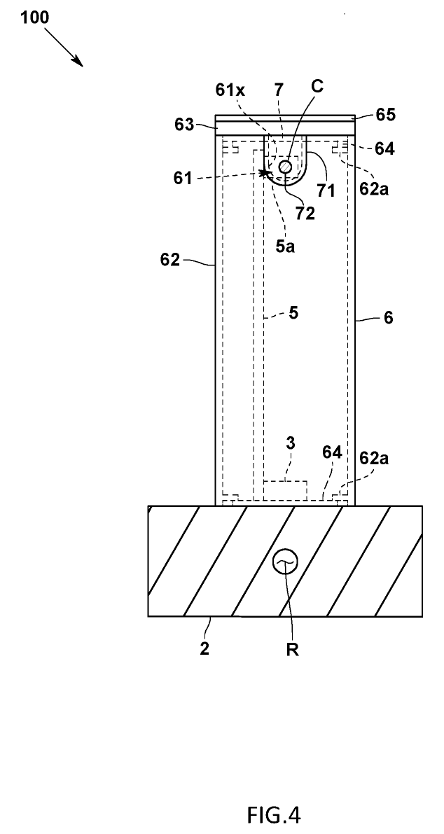

Furthermore, as is shown in FIG. 4, the through portion 61 is formed by cutting a notch in a side wall of the housing main body 62 extending downwards from an upper end portion of the housing main body 62. Here, in a side view looking from the side wall in which the through portion 61 is formed, it can be seen that the through portion 61 is formed by cutting a notch in the side wall of the housing main body 62 such that a bottom portion of a surface 61x in which the through portion 61 is formed has a circular arc shape.

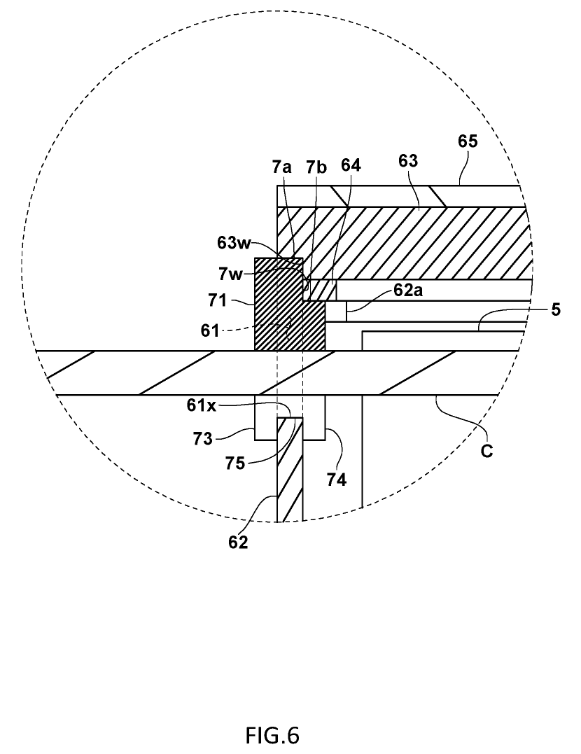

The lid body 63 is formed having a substantially rectangular planar configuration so that a lower surface of the lid body 63 covers the upper portion aperture of the housing main body 62. In the present embodiment, as can be seen in FIG. 1 in particular, and in FIG. 6, the lid body 63 abuts against an upper end surface of the housing main body 62 and an upper surface of a sealing component 64. In addition, a connecting wall 63w that connects an abutting surface of the lid body 63 that abuts against the upper end surface of the housing main body 62 with an abutting surface of the lid body 63 that abuts against the upper surface of a sealing component 64 is formed in the lid body 63. In the present embodiment, the connecting wall 63w abuts against a side surface of the housing main body 62. As a result, the lid body 63 is properly positioned on the housing main body 62. As is shown in FIG. 2 and FIG. 3, bolt holes bh through which are inserted bolts B that fix the lid body 63 and the sealing components 64 to the housing main body 62 are formed in the four corners of the lid body 63.

Note that, in the present embodiment, a single bolt B that penetrates the housing main body 62, the lid body 63, and the sealing components 64 is inserted through each one of the bolt holes bh, however, it is also possible for different bolts B to have different functions. For example, the bolts B may be separated into bolt elements that fasten together the flow path block 2, the housing main body 62, and a sealing component 64, and bolt elements that fasten together the housing main body 62, the lid body 63, and a sealing component 64.

As is shown in FIG. 2, through holes 63h that penetrate from the upper surface of the lid body 63 to the lower surface thereof are formed in the lid body 63. The through holes 63h are holes that may be used, for example, as communication ports or as maintenance holes or the like. Note that a surface sealing material 65 that covers the through holes 63h is further provided on the housing 6.

The sealing components 64 are formed having a substantially rectangular-frame shaped configuration. Here, as is shown in FIG. 1 and FIG. 4, a sealing component 64 is provided respectively on an upper end portion and a lower end portion of the housing main body 62. More specifically, as is shown in FIG. 3, the sealing components 64 are formed having a frame shape that follows an aperture rim of the upper end portion of the housing main body 62 and an aperture rim of the lower end portion thereof.

In the present embodiment, as is shown in FIG. 1 through FIG. 4 and in FIG. 6, a positioning portion 62a that positions the sealing component 64 is formed respectively in each of an aperture rim of the upper end portion of the housing main body 62 and an aperture rim of the lower end portion thereof. Note that, as is shown in FIG. 3, the bolt holes bh through which the bolts B are inserted are formed in the four corners of the sealing components 64.

The positioning portions 62a are formed so as to follow the shape of the aperture rim of the upper end portion of the housing main body 62 and the aperture rim of the lower end portion thereof. More specifically, as is shown in FIG. 1 and FIG. 4, the positioning portions 62a are formed by recessed portions that are hollowed out in a downward direction from the upper end portion of the housing main body 62 and by recessed portions that are hollowed out in an upward direction from the lower end portion of the housing main body 62. In a state in which the lower surface of a sealing component 64 abuts against the bottom surface of a positioning portion 62a, the sealing component 64 is positioned relative to the housing main body 64 as a result of the side surfaces of the sealing component 64 coming into contact with the side surfaces of the positioning portion 62a that are extending upright from the bottom surface of the positioning portion 62a. Note that, as is shown in FIG. 3, the bolt holes bh through which the bolts B are inserted are formed in the four corners of the positioning portions 62a.

Consequently, as is shown in FIG. 4 and FIG. 6, a packing 7 is provided between the surface 61x of the housing 6 in which the through portion 61 is formed and the cable C so as to plug the gap that is formed between these. The packing 7 is provided in the side wall in which the through portion 61 is formed. As is shown in FIG. 4 through FIG. 6, the packing 7 includes an annular portion 71 that is formed having an annular shape and in which a holding aperture 7h that holds the cable C is formed so as to penetrate the packing 7 in the thickness direction thereof, and a slit 72 that is formed extending from an outer side circumferential surface of the annular portion 71 towards the holding aperture 7h. Note that the packing 7 is formed by an elastic component made, for example, from resin or the like.

The annular portion 71 provides an airtight seal between the surface 61x in which the through portion 61 is formed and the cable C. More specifically, as can be seen in FIG. 6 in particular, by inserting the cable C into the holding aperture 7h through the slit 72, the holding aperture 7h holds the cable C via an airtight seal. If the annular portion 71 is then fitted into the through portion 61 so as to block off the through portion 61, then the gap between the surface 61x in which the through portion 61 is formed and the cable C is blocked via an airtight seal.

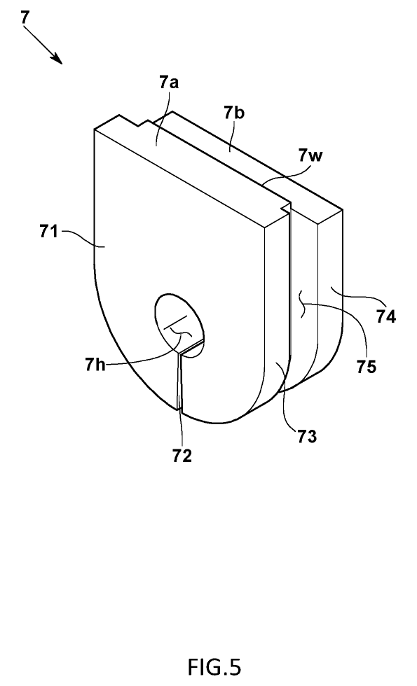

As is shown in FIG. 5 and FIG. 6, an outer side sealing portion 73 that seals an outer surface of the side wall in which the through portion 61 is formed, and an inner side sealing portion 74 that seals an inner surface of the side wall in which the through portion 61 is formed are formed in an outer circumferential portion of the annular portion 71. The outer side sealing portion 73 and the inner side sealing portion 74 are mutually connected together, and sandwich both surfaces of the side wall in which the through portion 61 is formed. More specifically, a groove portion 75 is formed between the outer side sealing portion 73 and the inner side sealing portion 74, and the outer side sealing portion 73 and the inner side sealing portion 74 are mutually connected together via this groove portion 75. By fitting the groove portion 75 into the side wall in which the through portion 61 is formed, the outer side sealing portion 73 and the inner side sealing portion 74 sandwich both surfaces of the side wall in which the through portion 61 is formed. Moreover, in this state, the bottom surface of the groove portion 75 abuts against the corresponding portion of the surface 61x in which the through portion 61 is formed.

Here, as is shown in FIG. 5 and FIG. 6, a step portion 7w is formed on the opposite side of the holding aperture 7h from the side where the slit 72 is formed by making the height of the upper end portion of the outer side sealing portion 73 different from the height of the upper end portion of the inner side sealing portion 74. More specifically, the upper end surface of the inner side sealing portion 74 is disposed at a lower position than the upper end surface of the outer side sealing portion 73. In the present embodiment, the upper end surface of the outer side sealing portion 73 and the upper end portion of the groove portion 75 are the same height. In a state in which the lid body 63 is covering the upper portion aperture of the housing main body 62, the upper end surface of the groove portion 75 functions as a lid body abutting portion 7a that abuts against the lid body 63. Moreover, in a state in which the lid body 63 is covering the upper portion aperture of the housing main body 62, the upper end surface of the inner side sealing portion 74 functions as a sealing component abutting portion 7b that abuts against the sealing component 64.

The lid body abutting portion 7a is a flat surface and abuts against an abutting surface of the lid body 63, which is a portion of the lower surface thereof that abuts against the upper end surface of the housing main body 62. In a state in which the packing 7 is mounted on the housing 6, the lid body abutting portion 7a is flush with the upper end surface of the housing main body 62.

The sealing component abutting portion 7b is a flat surface and abuts against the lower surface of the sealing component 64. In a state in which the packing 7 is mounted on the housing 6, the sealing component abutting portion 7b is flush with the bottom surface of the positioning portion 62a, and a portion of the sealing component abutting portion 7b is positioned on the inner side of the sealing component 64.

### Method of Assembling the Fluid Control Apparatus

Next, a method of assembling the fluid control apparatus of the present embodiment will be described.

Firstly, the fluid sensor 3, the fluid control valve 4, and the control board 5 are mounted on one surface of the flow path block 2.

Next, a sealing component 64 is placed on the one surface of the flow path block 2 so that the fluid sensor 3 and the control board 5 are enclosed within the frame of the sealing component 64. Note that it is also possible to firstly place the sealing component 64 on the one surface of the flow path block 2, and to subsequently mount the fluid sensor 3 and the control board 5 on the one surface of the flow path block 2 within the frame of the sealing component 64.

Next, the housing main body 62 is placed on the one surface of the flow path block 2 on which the sealing component 64 has already been placed. More specifically, the positioning portion 62a that is formed on the lower end portion of the housing main body 62 is abutted against the sealing component 64. As a result, the fluid sensor 3 and the control board 5 are enclosed by the housing main body 62, and the fluid control valve 4 is disposed on the outside of the housing main body 62.

Next, the cable C is inserted through the through portion 61, and the outside extension portion 4a of the fluid control valve 4 is electrically connected by the cable C to the connector 5a of the control board 5.

Next, the gap between the surface 61x of the housing main body 62 in which the through portion 61 is formed and the cable C is plugged by the packing 7. More specifically, the cable C is inserted into the slit 72 formed in the packing 7, and the cable C is then further pressed from the slit 72 in the packing 7 so that it becomes fitted inside the holding aperture 7h. The side wall in which the through portion 61 is formed is then sandwiched from both sides by the inward facing surface of the outer side sealing portion 73 and the outward facing surface of the inner side sealing portion 74. In this state, the lid body abutting portion 7a is at the same height as the upper end surface of the housing main body 62, and the sealing component abutting portion 7b is flush with the bottom surface of the positioning portion 62a that is formed on the upper end portion of the housing main body 62.

Next, the sealing component 64 is positioned as a result of the sealing component 64 being abutted against the positioning portion 62a formed in the upper end portion of the housing main body 62. In this state, the upper end surface of the housing main body 62 is flush with the lid body abutting portion 7a.

Next, the upper portion aperture of the housing main body 62 is covered by the lid body 63. The portion of the lower surface of the lid body 63 that is located above the connecting wall 63w abuts against the upper end surface of the housing main body 62 and the lid body abutting portion 7a. In addition, the portion of the lower surface of the lid body 63 that is located below the connecting wall 63w abuts against the upper surface of the sealing component 64. The lower surface of the sealing component 64 abuts against the positioning portion 62a and the sealing component abutting portion 7b. Accordingly, as a result of the lid body 63 covering the upper portion aperture of the housing main body 62, the packing 7 is fixed to the housing main body 62 via the sealing component 64.

Next, the bolts B are inserted into the bolt holes bh that are formed in the positioning portions 62a, the lid body 63, and the sealing components 64. The bolts B are then screwed in so that the housing 6 is fixed to the flow path block 2.

### Effects Obtained from the First Embodiment

According to the fluid control apparatus 100 of the first embodiment, because the packing 7 is provided between the cable C and the through portion 61 so as to plug the gap between these, even if the fluid control valve 4 is disposed outside the housing 6, it is still possible to prevent dust and moisture from entering into the inside of the housing 6 through the gap between the cable C and the through portion 61. As a result, it is possible to prevent the control board 5 and the like from malfunctioning because of dust and/or moisture and the like.

In addition, because the fluid control valve 4 is provided outside the housing 6 and the housing 6 is tightly sealed, it is possible to prevent heat from the fluid control valve 4 having an adverse effect on electronic components and the like housed inside the housing 6, and to thereby prevent the flow rate measurement accuracy from being adversely affected.

Note that, because the fluid control valve 4 is located outside the housing 6, it is possible to prevent the control board 5 and the like from malfunctioning because of heat discharged from the fluid control valve 4.

### Second Embodiment of the Present Invention

Hereinafter, a fluid control apparatus according to a second embodiment of the present invention will be described using the drawings. Note that, in the following description, portions that are different than those in the first embodiment are described, and any structure that is the same as in the first embodiment is described using the same symbols.

In the first embodiment, the through portion 61 is formed by cutting a notch in the housing main body 62, however, in the second embodiment, unlike in the first embodiment, the through portion 61 is formed by cutting a notch in the lid body 63.

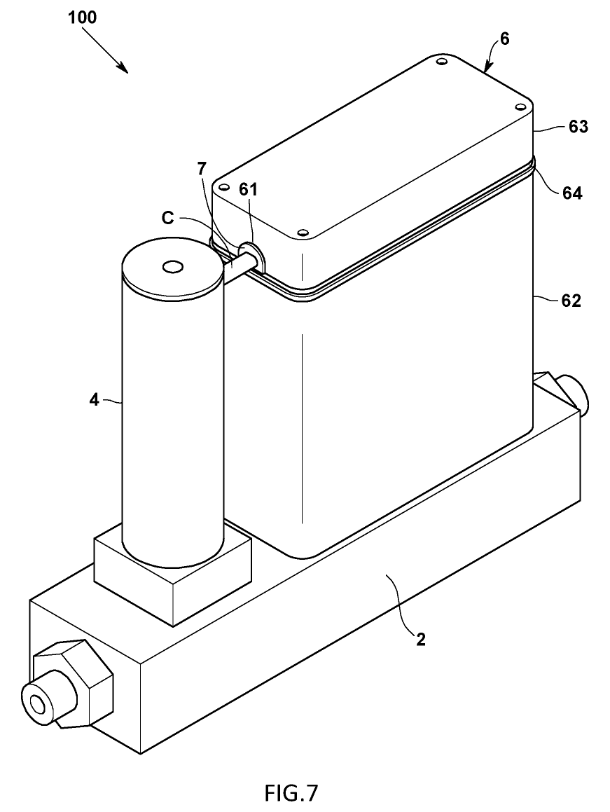

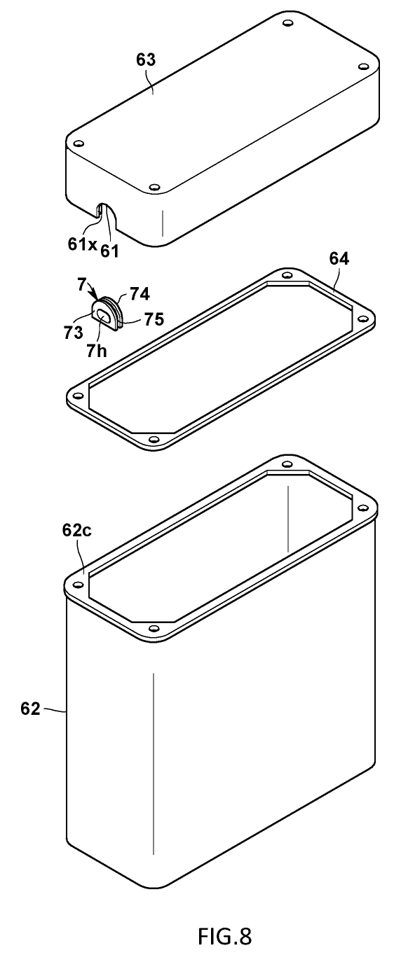

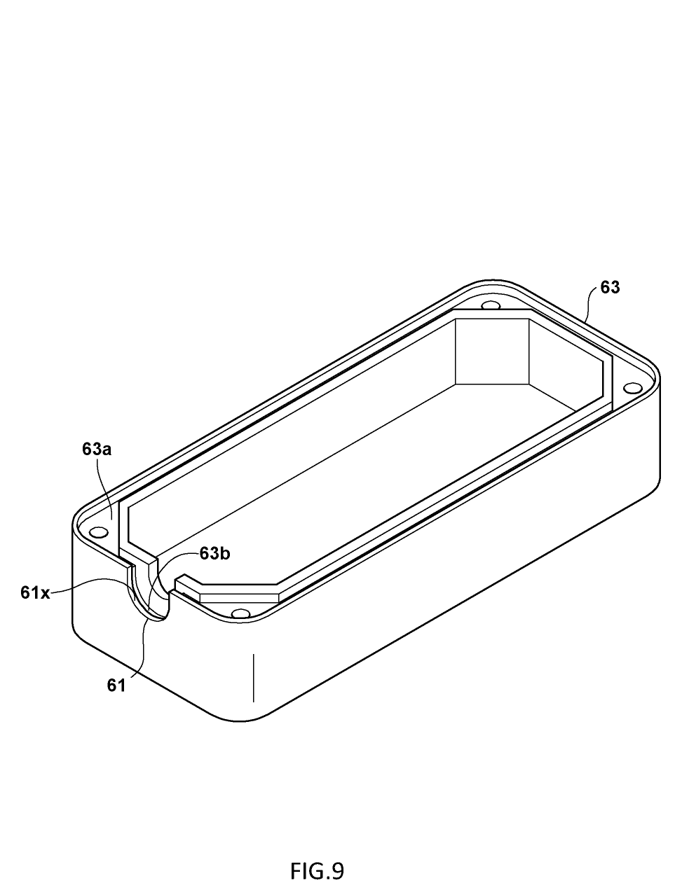

More specifically, as is shown in FIG. 7 and FIG. 8, the through portion 61 is formed by cutting a notch in an upward direction from the lower end portion of the lid body 63. Even more specifically, the through portion 61 is formed in a side wall of the lid body 63 by cutting a notch in an upward direction from the lower end portion of the side wall. Here, as can be seen in FIG. 8 in particular, and in FIG. 9, the through portion 61 is formed by cutting a notch in the side wall of the lid body 63 such that a bottom portion of a surface 61x in which the through portion 61 is formed has a circular arc shape.

In the second embodiment, as is shown in FIG. 9 in particular, a seal positioning portion 63a that positions the sealing component 64 is formed in the lid body 63. More specifically, the sealing component 64 is formed having a frame shape, and the seal positioning portion 63a is a groove that is formed in a surface of the lid body 63 that closes off the upper portion aperture of the housing main body 62, and into which the sealing component 64 is fitted. As a result of the sealing component 64 being fitted into the seal positioning portion 63a, the sealing component 64 is positioned relative to the lid body 63.

Here, as is shown in FIG. 8, a sealing component placement portion 62c on which the sealing component 64 is placed is formed on the upper end portion of the housing main body 62. More specifically, the sealing component placement portion 62c is a surface that is formed on the aperture rim of the upper end portion of the housing main body 62, and is also a surface that is formed on the aperture rim of the lower end portion of the housing main body 62. Even more specifically, the sealing component placement portions 62c are frame-shaped surfaces that match the configuration of the sealing component 64. The sealing component 64 is positioned relative to the housing 6 by placing one surface of the sealing component 64 in contact with a sealing component placement portion 62c, and then, in this state, by fitting the other surface of the sealing component 64 into the seal positioning portion 63a.

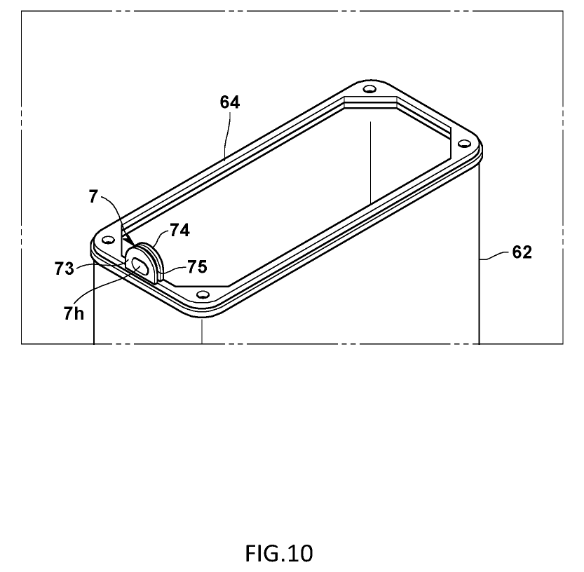

In the second embodiment, the packing 7 is provided in a side wall of the lid body 63 in which the through portion 61 is formed. As is shown in FIG. 8 and FIG. 10, the packing 7 is formed having a substantially annular configuration, and a holding aperture 7h that holds the cable C is formed so as to penetrate the packing 7 in the thickness direction thereof. The holding aperture 7h is able to hold the cable C via an airtight seal, and the cable C is inserted through this holding aperture 7h. Note that the packing 7 of the second embodiment does not include a slit that is formed extending from the outer side circumferential surface towards the holding aperture 7h, however, it is also possible for such a slit to be provided.

More specifically, the packing 7 includes an outer side sealing portion 73 that seals an outer surface of the side wall of the lid body 63 in which the through portion 61 is formed, and an inner side sealing portion 74 that seals an inner surface of the side wall of the lid body 63 in which the through portion 61 is formed. An outer circumferential surface of the outer side sealing portion 73 and an outer circumferential surface of the inner side sealing portion 74 are formed by a circular-arc shaped area that is formed as a circular arc matching the shape of the through portion 61, and a flat area that is formed as a flat portion on the opposite side from the circular arc area.

A groove portion 75 is formed between the outer side sealing portion 73 and the inner side sealing portion 74, and the outer side sealing portion 73 and the inner side sealing portion 74 are mutually connected together via this groove portion 75. By fitting the side wall of the lid body 63 in which the through portion 61 is formed into the groove portion 75, the outer side sealing portion 73 and the inner side sealing portion 74 sandwich both surfaces of the side wall of the lid body 63 in which the through portion 61 is formed. Moreover, in this state, the bottom surface of the groove portion 75 abuts against the corresponding portion of the surface 61x in which the through portion 61 is formed.

Here, as can be seen in FIG. 9 in particular, a packing positioning portion 63b that positions the inner side sealing portion 74 of the packing 7 is formed in the surface of the lid body 63 that closes off the upper portion aperture of the housing main body 62. More specifically, the packing positioning portion 63b is a groove into which the circular arc area of the inner side sealing portion 74 is fitted. As a result of the seal positioning portion 63a and the packing positioning portion 63b being formed in the lid body 63, the lid body 63 is able to properly position the sealing component 64 and the packing 7.

In a state in which circular arc area of the inner side sealing portion 74 is fitted into the packing positioning portion 63b, the flat area of the inner side sealing portion 74 abuts against the upper surface of the sealing component 64. By adopting this structure, in a state in which the lid body 63 has closed off the upper portion aperture of the housing main body 62, because the flat area of the inner side sealing portion 74 and the upper surface of the sealing component 64 are in tight contact with each other, no gap can be created between the packing 7 and the sealing component 64.

### Additional Embodiments

Note that the present invention is not limited to the above-described embodiments.

In the above-described first embodiment and second embodiment, the through portion 61 is formed in one of either a side wall of the housing main body 62 or a side wall of the lid body 63, however, it is also possible for a through portion to be formed in both of these.

In the above-described first embodiment and second embodiment, a positioning portion that positions the sealing component 64 provided on the upper portion is formed in one of either the housing main body 62 or the lid body, however, it is also possible for a positioning portion to be formed in both of these.

In the above-described first embodiment and second embodiment, a positioning portion that positions the sealing component 64 provided on the lower portion is formed in the housing main body 62, however, it may instead be formed on one surface of the flow path block 2 on which the housing 6 is mounted, or a positioning portion may be formed in both of these locations.

In the above-described first embodiment, a structure is adopted in which the lid body 63 includes the connecting wall 63w that connects the abutting surface of the lid body 63 that abuts against the upper end surface of the housing main body 62 with the abutting surface of the lid body 63 that abuts against the upper surface of the sealing component 64, however, it is also possible to adopt a structure in which the bottom surface of the lid body 63 does not include the connecting wall 63w. In other words, it is also possible to adopt a structure in which the abutting surface that abuts against the upper end surface of the housing main body 62 and the abutting surface that abuts against the upper surface of the sealing component 64 are mutually flush surfaces. In this case, the upper surface of the sealing component 64, the upper surface of the housing 6, and the lid body abutting portion 7a of the packing 7 are all mutually flush surfaces.

In the above-described first embodiment and second embodiment, the housing main body 62 and the lid body 63 are mutually independent components, however, it is also possible for the housing main body 62 and the lid body 63 to be formed as a single unit.

In the above-described first embodiment and second embodiment, the packing 7 is a single component in which the outer side sealing portion 73 and the inner side sealing portion 74 are mutually connected, however, it is also possible for the packing 7 to be separated into two independent components, namely, an outer side packing element that forms the outer side sealing portion 73 and an inner side packing element that forms the inner side sealing portion 74.

In the above-described first embodiment, a structure is adopted in which the packing 7 includes the slit 72, however, it is also possible for the packing 7 to not include the slit 72. In this case, after the cable C has been inserted through the holding aperture 7h, the cable C is connected to the outside extension portion 4a of the fluid control valve 4 or the connector 5a of the control board 5.

In the above-described first embodiment, the through portion 61 is formed by cutting a notch that extends downwards from the upper end portion of the housing main body 62, however, the present invention is not limited to this. It is also possible for the through portion 61 to be formed as a through hole that is located a predetermined distance apart from the upper end portion of the housing main body 62.

In the above-described first embodiment, the positioning portion 62a is a recessed portion formed in the housing main body 62, however, the present invention is not limited to this. For example, it is also possible for a recessed portion to be formed in the sealing component 64, and for the positioning portion 62a to be a protruding portion that fits inside this recessed portion formed in the sealing component 64. In this case, when looked at in a side view, the sealing component abutting portion 7b may be formed at the same height as the upper end surface of the outer side sealing portion 73, or at a different height than this upper end surface.

In the above-described first embodiment and second embodiment, the housing 6 is provided with the surface sealing material 65, however, it is also possible for the surface sealing material 65 to not be provided.

In the above-described first embodiment and second embodiment, it is also possible, after the gap between the cable C and the through portion 61 has been plugged by the packing 7, for the cable C to be inserted through the through portion 61, and for the outside extension portion 4a of the fluid control valve 4 and the connector 5a of the control board 5 to be electrically connected by means of this cable C.

Furthermore, it should be understood that the present invention is not limited to the above-described embodiments, and that various modifications and the like may be made thereto insofar as they do not depart from the spirit or scope of the present invention.

According to the present invention, in a case in which a fluid control valve is disposed outside a housing, it is possible to prevent dust and moisture from entering the inside of that housing.

### REFERENCE CHARACTER LIST

100 Fluid Control Apparatus

2 Flow Path Block

3 Fluid Sensor

4 Fluid Control Valve

4a Outside Extension Portion

5 Control Board

5a Connector

6 Housing

61 Through Portion

61x Surface in which Through Portion is Formed

62 Housing Main Body

63 Lid Body

64 Sealing Component

65 Surface Sealing Material

7 Packing

71 Annular Portion

72 Slit

73 Outer Side Sealing Portion

74 Inner Side Sealing Portion

7a Sealing Component Abutting Portion

7h Holding Aperture

What is claimed is:

1. A fluid control apparatus that controls a fluid flowing through a flow path, comprising:
a fluid control valve that controls the fluid;
a control board that controls the fluid control valve; and
a housing that houses the control board, wherein
the fluid control valve is disposed outside the housing,
a through portion through which passes a cable that connects a connector provided on the control board to the fluid control valve is formed in the housing, and
there is provided a packing that plugs a gap between a surface of the housing in which the through portion is formed and the cable.

2. The fluid control apparatus according to claim 1, wherein the housing includes:
a housing main body that is formed in a cylindrical shape having at least an upper portion aperture formed therein;
a lid body that covers the upper portion aperture in the housing main body; and
a sealing component that is interposed between the housing main body and the lid.

3. The fluid control apparatus according to claim 2, wherein
the through potion is formed by cutting a notch extending downwards from an upper end portion of the housing main body and/or extending upwards from a lower end portion of the housing main body, and
the packing has a sealing component abutting portion that, in a state in which the lid body is covering the upper portion aperture of the housing main body, abuts against the sealing component.

4. The fluid control apparatus according to claim 2, wherein
the housing includes side wall portions that surround side portions of the control board, and
the through portion is formed in a side of the side wall portions that faces the fluid control valve and/or in a side of the lid body that faces the fluid control valve.

5. The fluid control apparatus according to claim 4, wherein
an outside extension portion, which is a portion of the fluid control valve where the cable extends from the fluid control valve to the outside, is provided in a side of the fluid control valve that faces the through portion.

6. The fluid control apparatus according to claim 1, wherein the packing includes:
an outer side sealing portion that seals an outer surface of the housing in which the through portion is formed; and
an inner side sealing portion that seals an inner surface of the housing in which the through portion is formed.

7. The fluid control apparatus according to claim 6, wherein the outer side sealing portion and the inner side sealing portion are mutually connected together, and sandwich both surfaces of the housing in which the through portion is formed.

8. The fluid control apparatus according to claim 1, wherein the packing includes:
an annular portion that is formed having an annular shape and in which a holding aperture that holds the cable is formed so as to penetrate the packing in the thickness direction thereof; and
a slit that is formed extending from an outer side circumferential surface of the annular portion towards the holding aperture, and that enables the cable to be fitted into the holding aperture.

9. The fluid control apparatus according to claim 2, wherein
the sealing component is formed having a frame shape that follows an aperture rim of the upper portion aperture formed in the housing main body, and
a positioning portion that positions the sealing component is formed in the aperture rim of the upper portion aperture of the housing main body and/or in the lid.

10. The fluid control apparatus according to claim 7, wherein
a through hole is formed in the lid body so as to penetrate from an upper surface to a lower surface thereof, and
the housing further comprises a surface sealing material that covers the through hole.

11. The fluid control apparatus according to claim 1, further comprising a flow path block inside which is formed the flow path, wherein
the fluid control valve, the control board, and the housing are provided on one surface of the flow path block.
